(19) United States
(12) Patent Application Publication
(10) Pub. No.: US 2024/0309511 A1
(43) Pub. Date: Sep. 19, 2024

(54) PLATING METHOD AND PLATING APPARATUS

(71) Applicant: Tokyo Electron Limited, Tokyo (JP)

(72) Inventors: Takeshi Nagao, Kikuchi-gun, Kumamoto (JP); Yuichiro Inatomi, Kikuchi-gun, Kumamoto (JP); Kazutoshi Iwai, Kikuchi-gun, Kumamoto (JP)

(21) Appl. No.: 18/263,435

(22) PCT Filed: Jan. 20, 2022
(86) PCT No.: PCT/JP2022/001927

§ 371 Date: Jul. 28, 2023

(30) Foreign Application Priority Data
Feb. 3, 2021 (JP) 2021-015670

(51) Int. Cl. C23C 18/16; C23C 18/40; H01L 21/288; H01L 21/768

(52) U.S. Cl. CPC C23C 18/1658; C23C 18/163; C23C 18/1632; C23C 18/1675; C23C 18/40; H01L 21/288; H01L 21/76838

(57) ABSTRACT

A plating method includes a preparation process; a first plating process; and a second plating process. In the preparation process, a substrate W having a seed layer 132 of cobalt or a cobalt alloy formed in a recess is prepared. In the first plating process, a displacement plating processing is performed on the substrate W to replace a surface layer of the seed layer 132 with copper by using a first plating liquid L1 containing a copper ion. In the second plating process, after the first plating process, a reduction plating processing is performed on the recess of the substrate W by using a second plating liquid L2 containing a copper ion and a reducing agent.

### TECHNICAL FIELD

The various aspects and embodiments described herein pertain generally to a plating method and a plating apparatus.

### BACKGROUND

Conventionally, as a way to form a multilayer wiring on a semiconductor wafer as a substrate, there is known a method of performing an electroless plating processing by using a copper seed layer formed in an inside of a via as a catalyst to fill the inside of the via with a copper wiring (see Patent Document 1).

### PRIOR ART DOCUMENT

Patent Document 1: Japanese Patent Laid-open Publication No. 2001-102448

### DISCLOSURE OF THE INVENTION

### Problems to be Solved by the Invention

Exemplary embodiments provide a technique capable of filling the inside of a via with a copper wiring successfully.

### Means for Solving the Problems

In an exemplary embodiment, a plating method includes a preparation process; a first plating process; and a second plating process. In the preparation process, a substrate having a seed layer of cobalt or a cobalt alloy formed in a recess is prepared. In the first plating process, a displacement plating processing is performed on the substrate to replace a surface layer of the seed layer with copper by using a first plating liquid containing a copper ion. In the second plating process, after the first plating process, a reduction plating processing is performed on the recess of the substrate by using a second plating liquid containing a copper ion and a reducing agent.

### Effect of the Invention

According to the exemplary embodiments, it is possible to fill the inside of the via with the copper wiring successfully.

### BRIEF DESCRIPTION OF THE DRAWINGS

FIG. 1 is a diagram illustrating a configuration of a substrate processing apparatus according to an exemplary embodiment.

FIG. 2 is a diagram illustrating a configuration of a plating unit according to the exemplary embodiment.

FIG. 3 is an enlarged cross sectional view illustrating a surface state of a substrate before being subjected to a first plating processing according to the exemplary embodiment.

FIG. 4 is a diagram for describing the first plating processing according to the exemplary embodiment.

FIG. 5 is an enlarged cross sectional view illustrating the surface state of the substrate after being subjected to the first plating processing according to the exemplary embodiment.

FIG. 6 is a diagram for describing a second plating processing according to the exemplary embodiment.

FIG. 7 is an enlarged cross sectional view illustrating the surface state of the substrate after being subjected to the second plating processing according to the exemplary embodiment.

FIG. 8 is a diagram for describing the first plating processing according to a modification example of the exemplary embodiment.

FIG. 9 is a diagram for describing the second plating processing according to the modification example of the exemplary embodiment.

FIG. 10 is a diagram for describing the second plating processing according to another modification example of the exemplary embodiment.

FIG. 11 is a flowchart illustrating a processing sequence in a plating processing according to the exemplary embodiment.

### DETAILED DESCRIPTION

Hereinafter, exemplary embodiments of a plating method and a plating apparatus according to the present disclosure will be described in detail with reference to the accompanying drawings. The present disclosure is not limited to the exemplary embodiments to be described below. Further, it should be noted that the drawings are schematic and relations in sizes of individual components and ratios of the individual components may sometimes be different from actual values. Even between the drawings, there may exist parts having different dimensional relationships or different ratios.

Conventionally, as a way to form a multilayer wiring on a semiconductor wafer as a substrate, there is known a method of performing an electroless plating processing by using a copper seed layer formed in an inside of a via as a catalyst to fill the inside of the via with a copper wiring.

Meanwhile, since the copper seed layer can only be formed by a PVD (Physical Vapor Deposition) method, it may not be possible to form the copper seed layer uniformly inside the via when an inner diameter of the via is reduced with a recent trend of miniaturization of the multilayer wiring.

As the copper seed layer is not uniformly formed inside the via, there is a concern that the inside of the via may not be appropriately filled with the copper wiring.

Thus, there is a demand for a technique capable of successfully filling the inside of the via with the copper wiring while overcoming the above-mentioned problems.

### <Outline of Substrate Processing System>

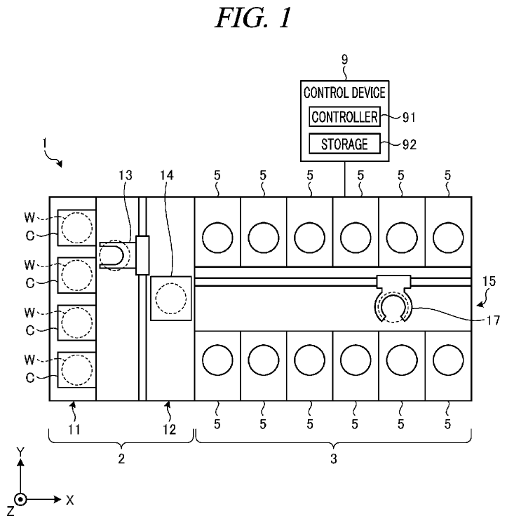

First, a schematic configuration of a substrate processing apparatus 1 according to an exemplary embodiment will be described with reference to FIG. 1. FIG. 1 is a diagram illustrating the configuration of the substrate processing system 1 according to the exemplary embodiment. The substrate processing apparatus 1 is an example of a plating apparatus.

Further, in the following, in order to clarify positional relationships, the X-axis, the Y-axis and the Z-axis which are orthogonal to each other will be defined, and the positive Z-axis direction will be regarded as a vertically upward direction.

As shown in FIG. 1, the substrate processing apparatus 1 includes a carry-in/out station 2 and a processing station 3. The carry-in/out station 2 and the processing station 3 are provided adjacent to each other.

The carry-in/out station 2 is equipped with a carrier placing table 11 and a transfer section 12. On the carrier placing table 11, a plurality of carriers C is placed to horizontally accommodate a plurality of substrates, i.e., semiconductor wafers (hereinafter, also referred to as “substrates W”) in the present exemplary embodiment.

A plurality of load ports is arranged on the carrier placing table 11 so as to be adjacent to the transfer section 12, and the carriers C are placed on the load ports one by one.

The transfer section 12 is provided adjacent to the carrier placing table 11, and has a substrate transfer device 13 and a delivery unit 14 therein. The substrate transfer device 13 is equipped with a wafer holding mechanism configured to hold the substrate W. Further, the substrate transfer device 13 is movable in horizontal and vertical directions and pivotable around a vertical axis, and it serves to transfer the substrate W between the carrier C and the delivery unit 14 by using the wafer holding mechanism.

The processing station 3 is disposed adjacent to the transfer section 12. The processing station 3 is equipped with a transfer section 15 and a plurality of plating units 5. The plurality of plating units 5 is arranged at both sides of the transfer section 15. A configuration of the plating unit 5 will be described later.

The transfer section 15 has a substrate transfer device 17 therein. The substrate transfer device 17 is equipped with a wafer holding mechanism configure to hold the substrate W. Further, the substrate transfer device 17 is movable in horizontal and vertical directions and pivotable around a vertical axis, and it serves to transfer the substrate W between the delivery unit 14 and the plating unit 5 by using the wafer holding mechanism.

Further, the substrate processing apparatus 1 is equipped with a control device 9. The control device 9 is, for example, a computer, and includes a controller 91 and a storage 92. The storage 92 stores therein a program for controlling various processings performed in the substrate processing apparatus 1. The controller 91 controls the operation of the substrate processing apparatus 1 by reading and executing the program stored in the storage 92.

Furthermore, the program may have been recorded in a computer-readable recording medium, and may be installed from the recording medium to the storage 92 of the control device 9.

The computer-readable recording medium may be, by way of non-limiting example, a hard disk (HD), a flexible disk (FD), a compact disk (CD), a magnet optical disk (MO), a memory card, or the like.

In the substrate processing apparatus 1 configured as described above, the substrate transfer device 13 of the carry-in/out station 2 first takes out the substrate W from the carrier C placed in the carrier placing table 11, and places the taken substrate W in the delivery unit 14.

The wafer W placed in the delivery unit 14 is taken out from the delivery unit 14 by the substrate transfer device 17 of the processing station 3 and carried into the plating unit 5 to be processed by the plating unit 5.

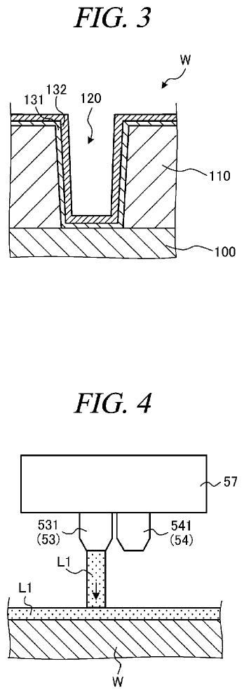

For example, a recess such as a trench or a via 120 (see FIG. 3) is formed on a front surface of the substrate W, and the plating unit 5 fills this recess with a metal by an electroless plating method.

The substrate W processed by the plating unit 5 is carried out from the plating unit 5 by the substrate transfer device 17, and placed in the delivery unit 14. The substrate W placed in the delivery unit 14 after being finished with the processing is returned back into the carrier C of the carrier placing table 11 by the substrate transfer device 13.

### <Outline of Plating Unit>

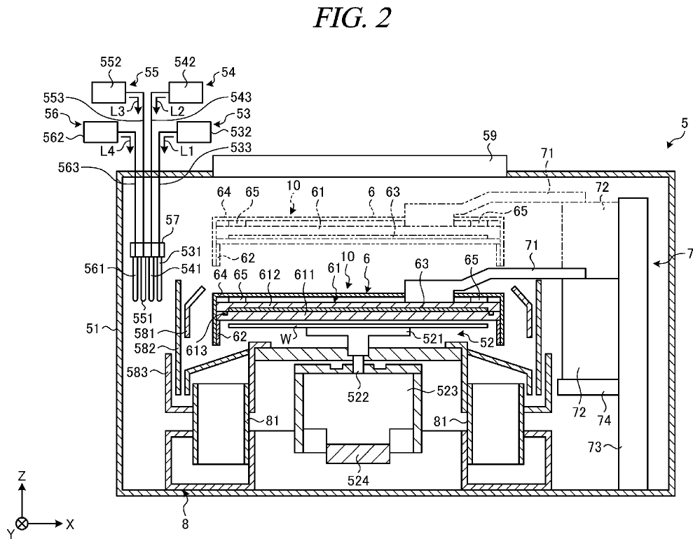

Now, a schematic configuration of the plating unit 5 will be explained with reference to FIG. 2. FIG. 2 is a diagram illustrating the configuration of the plating unit 5 according to the exemplary embodiment. For example, the plating unit 5 is configured as a single-wafer processing unit configured to process the substrates W one by one.

The plating unit 5 is configured to perform a liquid processing including an electroless plating processing. The plating unit 5 includes a chamber 51, a substrate holder 52, a first plating liquid supply 53, and a second plating liquid supply 54. The first plating liquid supply 53 and the second plating liquid supply 54 are an example of a chemical liquid supply.

The substrate holder 52 is disposed in the chamber 51 to hold the substrate W horizontally. The first plating liquid supply 53 is configured to supply a first plating liquid L1 to the front surface (top surface) of the substrate W held by the substrate holder 52. The second plating liquid supply 54 is configured to supply a second plating liquid L2 to the front surface (top surface) of the substrate W held by the substrate holder 52.

In the exemplary embodiment, the substrate holder 52 has a chuck member 521 configured to vacuum-attract a bottom surface (rear surface) of the substrate W. The chuck member 521 is of a so-called vacuum chuck type.

A rotation motor 523 (rotational driving unit) is connected to the substrate holder 52 via a rotation shaft 522. When this rotation motor 523 is driven, the substrate holder 52 is rotated along with the substrate W. The rotation motor 523 is supported by a base 524 fixed to the chamber 51. Further, a heating source such as a heater is not provided inside the substrate holder 52.

The first plating liquid supply 53 includes a first plating liquid nozzle 531 configured to discharge (supply) the first plating liquid L1 to the substrate W held by the substrate holder 52, and a first plating liquid source 532 configured to supply the first plating liquid L1 to the first plating liquid nozzle 531.

The first plating liquid source 532 is configured to supply the first plating liquid L1 heated or regulated to a predetermined temperature to the first plating liquid nozzle 531 via a first plating liquid line 533.

The temperature of the first plating liquid L1 when it is discharged from the first plating liquid nozzle 531 is in the range of, e.g., 40° C. to 70° C., more desirably, in the range of 60° C. to 70° C. The first plating liquid nozzle 531 is held by a nozzle arm 57 to be movable.

The first plating liquid L1 is a plating liquid for a displacement-type electroless plating processing (hereinafter also referred to as a displacement plating processing). The first plating liquid L1 contains, for example, copper (Cu) ions. Further, the first plating liquid L1 according to the exemplary embodiment contains a reducing agent only in a proportion smaller than a preset value, or contains no reducing agent.

The reducing agent that can be contained in the first plating liquid L1 may be, by way of non-limiting example, hypophosphorous acid, dimethylamineborane, glyoxylic acid, or the like.

The second plating liquid supply 54 includes a second plating liquid nozzle 541 configured to discharge (supply) the second plating liquid L2 to the substrate W held by the substrate holder 52, and a second plating liquid source 542 configured to supply the second plating liquid L2 to the second plating liquid nozzle 541.

The second plating liquid source 542 is configured to supply the second plating liquid L2 heated or regulated to a preset temperature to the second plating liquid nozzle 541 via a second plating liquid line 543.

The temperature of the second plating liquid L2 when it is discharged from the second plating liquid nozzle 541 is in the range of, e.g., 40° C. to 70° C., more desirably, in the range of 60° C. to 70° C. The second plating liquid nozzle 541 is held by the nozzle arm 57 to be movable.

The second plating liquid L2 is a plating liquid for a reduction-type electroless plating processing (hereinafter also referred to as a reduction plating processing). The second plating liquid L2 contains, for example, copper ions, and a reducing agent in a proportion larger than that of the first plating liquid L1. The reducing agent included in the second plating liquid L2 is, for example, hypophosphorous acid, dimethylamineborane, glyoxylic acid, or the like.

Further, the second plating liquid L2 according to the exemplary embodiment may contain a complexing agent or a pH adjuster in addition to the metal ions and the reducing agent. The complexing agent that can be included in the second plating liquid L2 is not particularly limited as long as it is capable of forming a complex with the copper ions, and examples thereof may include oxycarboxylic acid or a salt thereof, aminocarboxylic acid or a salt thereof, triethanolamine, glycerin, or the like.

The oxycarboxylic acid may be, by way of non-limiting example, lactic acid, malic acid, tartaric acid, citric acid, gluconic acid, or the like. The aminocarboxylic acid may be, by way of example, but not limitation, nitrilotriacetic acid, ethylenediaminetetraacetic acid (EDTA), hydroxyethylethylenediaminetriacetic acid, diethylenetriaminepentaacetic acid, triethylenetetraminehexaacetic acid, 1,3-propanediaminetetraacetic acid, or the like.

Further, the pH adjuster that can be included in the second plating liquid L2 may be, by way of example, sodium oxide, tetramethylammonium hydroxide (TMAH), potassium hydroxide, ammonia, or the like.

The plating unit 5 further includes a cleaning liquid supply 55 configured to supply a cleaning liquid L3 to the front surface of the substrate W held by the substrate holder 52, and a rinse liquid supply 56 configured to supply a rinse liquid L4 to the front surface of the corresponding substrate W.

The cleaning liquid supply 55 supplies the cleaning liquid L3 to the substrate W held and being rotated by the substrate holder 52 to pre-clean the substrate W. The cleaning liquid supply 55 includes a cleaning liquid nozzle 551 configured to discharge the cleaning liquid L3 to the substrate W held by the substrate holder 52, and a cleaning liquid source 552 configured to supply the cleaning liquid L3 to the cleaning liquid nozzle 551.

The cleaning liquid source 552 is configured to supply the cleaning liquid L3 heated or regulated to a predetermined temperature to the cleaning liquid nozzle 551 via a cleaning liquid line 553 as will be described later. The cleaning liquid nozzle 551 is held by the nozzle arm 57 to be movable along with the first plating liquid nozzle 531 and the second plating liquid nozzle 541.

As the cleaning liquid L3, dicarboxylic acid or tricarboxylic acid is used. The dicarboxylic acid may be, by way of non-limiting example, an organic acid such as malic acid, succinic acid, malonic acid, oxalic acid, glutaric acid, adipic acid, or tartaric acid. Further, as an example of the tricarboxylic acid, an organic acid such as citric acid may be used.

The rinse liquid supply 56 includes a rinse liquid nozzle 561 configured to discharge the rinse liquid L4 to the substrate W held by the substrate holder, and a rinse liquid source 562 configured to supply the rinse liquid L4 to the rinse liquid nozzle 561.

The rinse liquid nozzle 561 is held by the nozzle arm 57 to be movable along with the first plating liquid nozzle 531, the second plating liquid nozzle 541 and the cleaning liquid nozzle 551.

Further, the rinse liquid source 562 is configured to supply the rinse liquid L4 to the rinse liquid nozzle 561 via a rinse liquid line 563. As an example of the rinse liquid L4, DIW (deionized water) or the like may be used.

The nozzle arm 57 holding the first plating liquid nozzle 531, the second plating liquid nozzle 541, the cleaning liquid nozzle 551, and the rinse liquid nozzle 561 described above is connected to a non-illustrated nozzle moving mechanism.

This nozzle moving mechanism is configured to move the nozzle arm 57 in horizontal and vertical directions. More specifically, the nozzle arm 57 is configured to be moved by the nozzle moving mechanism between a discharge position where the processing liquid (the first plating liquid L1, the second plating liquid L2, the cleaning liquid L3 or the rinse liquid L4) is discharged to the substrate W and a retreat position where the nozzle arm 57 is retreated from the discharge position.

Here, the discharge position is not particularly limited as long as the processing liquid can be supplied to a certain position on the front surface of the substrate W. By way of example, appropriately, the discharge position may be set such that the processing liquid can be supplied to the center of the substrate W.

The discharge position of the nozzle arm 57 may be different when the first plating liquid L1 is supplied to the substrate W, when the second plating liquid L2 is supplied to the substrate W, when the cleaning liquid L3 is supplied to the substrate W, and when the rinse liquid L4 is supplied to the substrate W.

The retreat position is a position far from the discharge position without being overlapped with the substrate W, when viewed from above. When the nozzle arm 57 is placed at the retreat position, interference between this nozzle arm 57 and a cover body 6 being moved can be avoided.

A cup 581 is disposed around the substrate holder 52. This cup 581 is formed in a ring shape when viewed from above, receives the processing liquid scattered from the substrate W when the substrate W is rotated, and guides the received processing liquid to a drain duct 583.

An atmosphere blocking cover 582 is provided around the cup 581 to suppress diffusion of an atmosphere around the substrate W in the chamber 51. This atmosphere blocking cover 582 has a cylindrical shape extending in a vertical direction with an open top. The cover body 6 to be described later is configured to be inserted into the atmosphere blocking cover 582 from above.

In the exemplary embodiment, the substrate W held by the substrate holder 52 is covered by the cover body 6. This cover body 6 has a ceiling member 61 and a sidewall member 62 extending downwards from the ceiling member 61.

The ceiling member 61 includes a first ceiling plate 611, and a second ceiling plate 612 provided on top of the first ceiling plate 611. A heater 63 is interposed between the first ceiling plate 611 and the second ceiling plate 612.

The first ceiling plate 611 and the second ceiling plate 612 are configured to seal the heater 63 so that the heater 63 does not come into contact with the processing liquid such as the second plating liquid L2. More specifically, a seal ring 613 is disposed around the heater 63, and the heater 63 is hermetically sealed by this seal ring 613.

It is desirable that the first ceiling plate 611 and the second ceiling plate 612 have corrosion resistance to the processing liquid such as the second plating liquid L2, and may be formed of, for example, an aluminum alloy. In order to improve the corrosion resistance, the first ceiling plate 611, the second ceiling plate 612, and the sidewall member 62 may be coated with Teflon (registered trademark).

A cover body moving mechanism 7 is connected to the cover body 6 via a cover body arm 71. The cover body moving mechanism 7 is configured to move the cover body 6 in horizontal and vertical directions. More specifically, the cover body moving mechanism 7 has a rotating motor 72 configured to move the cover body 6 in the horizontal direction and a cylinder 73 configured to move the cover body 6 in the vertical direction.

Here, the rotating motor 72 is mounted on a supporting plate 74 provided so as to be vertically movable with respect to the cylinder 73. Instead of the cylinder 73, an actuator (not shown) including a motor and a ball screw may be used.

The rotating motor 72 of the cover body moving mechanism 7 moves the cover body 6 between an upper position disposed above the substrate W held by the substrate holder 52 and a retreat position retreated from the upper position. Here, the upper position is a position facing the substrate W held by the substrate holder 52 at a relatively large distance therebetween, and is a position overlapping the substrate W when viewed from above.

The retreat position is a position within the chamber 51 that does not overlap the substrate W when viewed from above. When the cover body 6 is located at the retreat position, interference between the nozzle arm 57 being moved and the cover body 6 is avoided. A rotational axis of the rotating motor 72 extends in the vertical direction, and the cover body 6 can be pivoted in the horizontal direction between the upper position and the retreat position.

The cylinder 73 of the cover body moving mechanism 7 moves the cover body 6 in the vertical direction to adjust a distance between the substrate W supplied with the second plating liquid L2 and the first ceiling plate 611 of the ceiling member 61. More specifically, the cylinder 73 locates the cover body 6 at a lower position (a position indicated by a solid line in FIG. 2) or the upper position (a position indicated by a dashed double-dotted line in FIG. 2).

In the exemplary embodiment, the heater 63 is driven to heat the substrate holder 52 or the second plating liquid L2 on the substrate W when the cover body 6 is located at the above-described lower position.

The ceiling member 61 and the sidewall member 62 of the cover body 6 are covered with a cover body cover 64. This cover body cover 64 is disposed on the second ceiling plate 612 of the cover body 6 with a plurality of supporting members 65 therebetween. That is, on the second ceiling plate 612, the plurality of supporting members 65 protruding upwards from a top surface thereof is provided, and the cover body cover 64 is disposed on these supporting members 65.

The cover body cover 64 is configured to be movable in the horizontal direction and the vertical direction along with the cover body 6. Further, it is desirable that the cover body cover 64 has heat insulation property higher than those of the ceiling member 61 and the sidewall member 62 in order to suppress heat within the cover body 6 from escaping to the vicinity thereof.

For example, it is desirable that the cover body cover 64 is made of a resin material, and it is more desirable that the resin material has heat resistance.

In the exemplary embodiment as described above, the cover body cover 64 and the cover body 6 equipped with the heater 63 are formed as one body. The cover body 6 and the cover body cover 64 constitutes a cover unit 10 which is configured to cover the substrate holder 52 or the substrate W when it is located at the lower position.

Above the chamber 51, there is provided a fan filter unit 59 configured to supply clean air near the cover body 6. The fan filter unit 59 supplies air into the chamber 51 (in particular, into the atmosphere blocking cover 582), and the supplied air flows toward an exhaust line 81.

A downflow of the air flowing downwards is formed around the cover body 6, and a gas vaporized from the processing liquid such as the second plating liquid L2 flows toward the exhaust line 81 by being carried with this downflow. Accordingly, the gas vaporized from the processing liquid is suppressed from rising and diffusing into the chamber 51.

The gas supplied from the above-described fan filter unit 59 is exhausted by an exhaust mechanism 8.

### Exemplary Embodiment

Now, details of a plating processing according to the exemplary embodiment will be described with reference to FIG. 3 to FIG. 7. FIG. 3 is an enlarged cross sectional view showing a state of the front surface of the substrate W before being subjected to a first plating processing according to the exemplary embodiment.

Further, non-illustrated devices are already formed on the substrate W shown in FIG. 3. Hereinafter, various kinds of processes of filling the via 120 formed in an insulating film 110 on a wiring 100 with a metal wiring in a wiring forming process after the formation of the devices (so-called BEOL (Back End of Line)) will be described.

As shown in FIG. 3, the wiring 100 made of a metal is formed on the substrate W, and the insulating film 110 is provided on the wiring 100. In the exemplary embodiment, the entire insulating film 110 is formed of an oxide film, for example.

The wiring 100 according to the exemplary embodiment is made of an element that does not diffuse into the insulating film 110, which is the oxide film. The wiring 100 is made of a conductive material containing, by way of non-limiting example, Co, Ni or Ru.

Further, the substrate W is provided with the via 120 formed at a certain position in the insulating film 110. The via 120 is an example of a recess, and is formed through the insulating film 110 to extend from a top surface of the insulating film 110 to the wiring 100.

In addition, prior to the first plating processing according to the exemplary embodiment, a barrier layer 131 composed of Ta or TaN and a seed layer 132 composed of cobalt (Co) or a cobalt alloy are sequentially formed on the front surface of the substrate W including the inside of the via 120.

Here, in the exemplary embodiment, the seed layer 132 made of, for example, cobalt or a cobalt alloy is formed by a CVD (Chemical Vapor Deposition) method.

Further, as a way to form the via 120 in the insulating film 110 of the substrate W, conventionally known methods may be appropriately employed. As a specific example, a general-purpose technique using a fluorine-based or chlorine-based gas may be used as a dry etching technique, for example.

In particular, as a method of forming the via 120 having a large aspect ratio (ratio of depth to diameter), an ICP-RIE (Inductively Coupled Plasma Reactive lon Etching) technique capable of achieving high-speed deep etching may be adopted.

For example, a so-called Bosch process in which an etching process using sulfur hexafluoride (SF₆) and a protection process using a gas such as C₄F₈ are repeatedly performed may be appropriately employed.

As illustrated in FIG. 3, the substrate W having the via 120 formed in the insulating film 110 on the wiring 100 and also having the barrier layer 131 and the seed layer 132 formed thereon is carried into the above-described plating unit 5, and then the preset plating processing is performed on the substrate W.

FIG. 4 is a diagram for explaining the first plating processing according to the exemplary embodiment. As shown in FIG. 4, in a plating method according to the exemplary embodiment, the controller 91 (see FIG. 1) first controls the first plating liquid supply 53 to discharge the first plating liquid L1 onto the front surface of the substrate W from the first plating liquid nozzle 531.

The controller 91 performs the displacement plating processing on the via 120 (see FIG. 3) by using this first plating liquid L1.

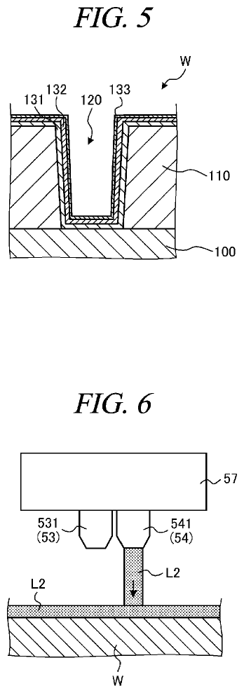

By this displacement plating processing, a surface layer of cobalt of the seed layer 132 formed inside the via 120 is replaced (displaced) with a thin film 133 of copper, as illustrated in FIG. 5. FIG. 5 is an enlarged cross sectional view showing the surface state of the substrate W after being subjected to the first plating processing according to the exemplary embodiment.

Then, in the plating method according to the exemplary embodiment, the controller 91 (see FIG. 1) controls the second plating liquid supply 54 to discharge the second plating liquid L2 onto the front surface of the substrate W from the second plating liquid nozzle 541, as shown in FIG. 6, following the above-described first plating processing. FIG. 6 is a diagram for describing a second plating processing according to the exemplary embodiment.

The controller 91 performs the reduction plating processing on the via 120 (see FIG. 5) by using this second plating liquid L2.

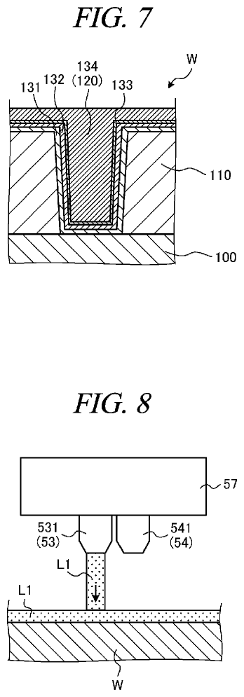

By this reduction plating processing, a reduction plating film 134 of copper is formed by using the thin film 133 of copper exposed inside the via 120 as a catalyst, so that the inside of the via 120 is filled with the reduction plating film 134, as illustrated in FIG. 7. FIG. 7 is an enlarged cross sectional view showing the surface state of the substrate W after being subjected to the second plating processing according to the exemplary embodiment.

As stated above, in the exemplary embodiment, the reduction plating film 134 is formed by using the thin film 133 formed by the displacement plating processing as the catalyst, so that the inside of the via 120 is filled with the reduction plating film 134. Accordingly, it is possible to form a proper copper wiring without having a void or a seam inside the via 120, where it is difficult to form the copper wiring due to its large aspect ratio.

Here, in the exemplary embodiment, the reduction plating processing is not performed directly on the seed layer 132 of cobalt. That is, the reduction plating processing is performed after replacing the surface layer of this seed layer 132 with the thin film 133 of copper. As a result, the inside of the via 120 can be appropriately filled with the copper wiring, as compared to the case where the reduction plating film 134 of copper is formed by using the cobalt as a catalyst.

In addition, if it is intended to form the reduction plating processing on the seed layer made of copper, such a seed layer of copper can only be formed by a typical PVD method. For this reason, there is a risk that a uniform seed layer may not be formed inside the via 120, particularly when the inner diameter of the via 120 is reduced along with miniaturization of the multilayer wiring.

In addition, such formation of the non-uniform seed layer inside the via 120 may raise a risk that the inside of the via 120 may not be appropriately filled with the reduction plating film 134 (i.e., the copper wiring).

In the present exemplary embodiment, however, since the seed layer 132 of cobalt, which can be formed by a method other than the PVD method as well, is used, it is possible to form uniformly the seed layer 132 in the via 120, as compared to the case where the seed layer of copper is formed. Therefore, according to the exemplary embodiment, the inside of the via 120 can be appropriately filled with the copper wiring, as compared to the case where the seed layer of copper is used.

Further, in the exemplary embodiment, the seed layer 132 of cobalt may be formed by a CVD method. Accordingly, the more uniform seed layer 132 may be formed inside the via 120. Therefore, according to the exemplary embodiment, the inside of the via 120 can be better filled with the copper wiring.

Moreover, in the exemplary embodiment, it is desirable that the seed layer 132 of cobalt has a thickness of 1 nm or more. In such a case, since the seed layer 132 in the form of a film shape rather than an island shape can be formed in the via 120, the seed layer 132 can be more uniformly formed inside the via 120. Therefore, according to the exemplary embodiment, the inside of the via 120 can be better filled with the copper wiring.

Additionally, in the exemplary embodiment, it is more desirable that the thickness of the seed layer 132 of cobalt is in the range of 2 nm to 5 nm. With such a thickness, the seed layer 132 can be more uniformly formed inside the via 120, so that deterioration in electrical resistance due to the thick seed layer 132 of cobalt can be suppressed.

Now, details of the first plating processing and the second plating processing described so far will be explained. The first plating processing is performed by supplying the first plating liquid L1 having, for example, a room temperature or a temperature higher than the room temperature (e.g., 23° C. to 70° C.) to the substrate W.

In this way, by performing the displacement plating processing with the first plating liquid L1 having the temperature higher than the room temperature, the surface layer of the seed layer 132 can be efficiently replaced with the thin film 133.

Further, the first plating processing may be performed while controlling the rotation speed of the substrate W to 1000 rpm or less. In this way, it is possible to suppress the first plating liquid L1 from being scattered off the front surface of the substrate W and being cut. Therefore, according to the exemplary embodiment, the displacement plating processing can be uniformly performed on the entire front surface of the substrate W.

The first plating processing may be performed while forming a puddle (accumulation) of the first plating liquid L1 on the front surface of the substrate W by controlling the substrate W to be rotated at a low speed (e.g., 20 rpm or thereabout), for example. Accordingly, in the first plating processing, the consumption amount of the first plating liquid L1 can be reduced.

Further, in the first plating processing, a process of forming the puddle of the first plating liquid L1 on the front surface of the substrate W and a process of scattering the puddle may be performed repeatedly.

Thus, in the first plating processing according to the exemplary embodiment, the consumption amount of the first plating liquid L1 can be reduced, and impurities such as the replaced cobalt can be removed from the first plating liquid L1, so that the thin film 133 in a good condition can be formed.

Further, the first plating processing may be performed while draining the first plating liquid L1, which is continuously supplied, from an end portion of the substrate W frequently by controlling the substrate W to be rotated at a relatively high speed (e.g., about 250 rpm), for example. Accordingly, in the first plating processing, since the impurities such as the replaced cobalt can be removed from the first plating liquid L1, the thin film 133 in a good condition can be formed.

In addition, it is desirable that the first plating processing is performed by using the first plating liquid L1 which does not contain the reducing agent, for example. Accordingly, it is possible to suppress a reaction between the metal ions and the reducing agent in the first plating liquid L1 stored in the first plating liquid source 532 (see FIG. 2), so that the processing efficiency of the first plating processing can be improved.

The second plating processing according to the exemplary embodiment may be performed while controlling the rotation speed of the substrate W to 100 rpm or less. Accordingly, since the reduction plating processing can be performed while forming a puddle of the second plating liquid L2 on the front surface of the substrate W, the consumption amount of the second plating liquid L2 can be reduced in the second plating processing.

Further, it is desirable that the substrate W on which the puddle of the second plating liquid L2 is formed is covered by the cover body 6 in the second plating processing, and the second plating processing is performed while raising the temperature of the puddle of the second plating liquid L2 to the preset temperature (e.g., 40° C. to 70° C.) with the heater 63 of the cover body 6.

Accordingly, since the reduction plating processing can be performed with the second plating liquid L2 whose temperature is higher than the room temperature, the inside of the via 120 can be better filled with the reduction plating film 134 even when the via 120 is miniaturized.

In addition, the temperature of the second plating liquid L2 in the second plating processing may be higher than the temperature of the first plating liquid L1 in the first plating processing. Accordingly, the second plating processing, which takes a longer time, can be efficiently performed, so that the overall processing time of the substrate W can be reduced.

In the second plating processing, the second plating liquid L2 is first supplied onto the front surface of the substrate W to form the puddle of the second plating liquid L2 on the front surface of the substrate W.

Then, the substrate W on which the puddle of the second plating liquid L2 is formed is covered by the cover body 6. In this case, the rotating motor 72 of the cover body moving mechanism 7 is first driven, so that the cover body 6 is pivoted in the horizontal direction to be located at the upper position (the position indicated by the dashed double-dotted line in FIG. 2).

Thereafter, the cylinder 73 of the cover body moving mechanism 7 is driven, so that the cover body 6 located at the upper position is lowered to be placed at the processing position. As a result, the distance between the second plating liquid L2 on the substrate W and the first ceiling plate 611 of the cover body 6 becomes a predetermined distance, so that the sidewall member 62 of the cover body 6 is disposed at a periphery side of the substrate W.

In the exemplary embodiment, a lower end of the sidewall member 62 of the cover body 6 is positioned lower than the bottom surface of the substrate W. In this way, the substrate W is covered by the cover body 6, and the space around the substrate W is blocked.

Next, the heater 63 is turned on, and the second plating liquid L2 accumulated on the substrate W is heated. A set temperature of the heater 63 is fixed to a target temperature enabling the second plating liquid L2 to reach the aforementioned preset temperature. The target temperature is, for example, 100° C. to 140° C.

When the temperature of the second plating liquid L2 is raised to a temperature at which components thereof are precipitated, the components of the second plating liquid L2 are precipitated on the front surface of the thin film 133, so that the reduction plating film 134 is formed.

Then, upon the lapse of a preset time after the heating by the heater 63 is begun, the heater 63 is turned off.

Subsequently, the cover body 6 is retreated from the substrate W. For example, the cover body moving mechanism 7 is driven to place the cover body 6 at the retreat position. Specifically, the rotating motor 72 of the cover body moving mechanism 7 is driven, so that the cover body 6 once located at the upper position is pivoted in the horizontal direction to be located at the retreat position, which ends the second plating processing.

Further, from the end of the first plating processing to the start of the second plating processing, the front surface of the substrate W needs to be in a state in which it is wet with the first plating liquid L1 (that is, in a state in which the liquid film of the first plating liquid L2 is formed on the front surface of the substrate W). Thus, the thin film 133 formed by the first plating processing can be suppressed from being oxidated by air.

That is, in the exemplary embodiment, since the second plating processing can be performed by using the thin film 133 in the good condition as the catalyst, the inside of the via 120 can be better filled with the reduction plating film 134.

### Various Modification Examples

Now, various modification examples of the exemplary embodiment will be described with reference to FIG. 8 to FIG. 10. FIG. 8 is a diagram for describing a first plating processing according to a modification example of the exemplary embodiment.

As depicted in FIG. 8, in a plating method according to the modification example, the controller 91 (see FIG. 1) first controls the first plating liquid supply 53 to discharge the first plating liquid L1 onto the front surface of the substrate W from the first plating liquid nozzle 531.

The controller 91 performs the displacement plating processing on the via 120 (see FIG. 3) by using the first plating liquid L1. By this displacement plating processing, the surface layer of the seed layer 132 of cobalt, which is formed inside the via 120, is replaced with the thin film 133 of copper. Further, since the first plating processing according to the modification example is the same as that of the above-described exemplary embodiment, detailed description thereof will be omitted.

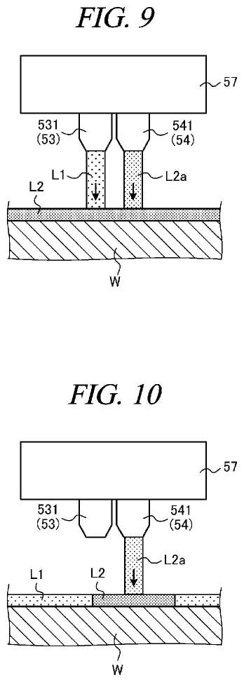

FIG. 9 is a diagram for describing a second plating processing according to the modification example. As depicted in FIG. 9, in the plating method according to the modification example, the controller 91 (see FIG. 1) controls the first plating liquid supply 53 to discharge the first plating liquid L1 onto the front surface of the substrate W from the first plating liquid nozzle 531, following the above-described first plating processing.

Further, in the modification example, the controller 91 controls the second plating liquid supply 54 to discharge a third plating liquid L2a onto the front surface of the substrate W from the second plating liquid nozzle 541. This third plating liquid L2a contains the reducing agent in a proportion larger than that of the first plating liquid L1 and does not contain copper ions.

In the modification example, the controller 91 produces the second plating liquid L2 in the second plating processing by discharging the first plating liquid L1 and the third plating liquid L2a onto the front surface of the substrate W and mixing them on the front surface of the substrate W. The controller 91 performs the reduction plating processing on the via 120 (see FIG. 5) by using the produced second plating liquid L2.

As a result, the reduction plating film 134 (see FIG. 7) is formed in the via 120. Since the second plating processing according to the modification example is the same as that of the above-described exemplary embodiment except that the first plating liquid L1 and the third plating liquid L2a are simultaneously discharged instead of the second plating liquid L2, detailed description thereof will be omitted here.

In the modification example described so far, the reduction plating processing is performed after the surface layer of the seed layer 132 of cobalt is replaced with the thin film 133 of copper, the same as in the above-described exemplary embodiment. Therefore, according to the modification example, the inside of the via 120 can be successfully filled with the copper wiring, the same as in the above-described exemplary embodiment.

Desirably, in the modification example, the first plating liquid L1 may not contain the reducing agent, and the third plating liquid L2a may contain the reducing agent and inevitable impurities. Further, in the modification example, the second plating liquid L2 may be prepared by mixing the first plating liquid L1 and the third plating liquid L2a on the front surface of the substrate W.

Accordingly, the reaction between the copper ions and the reducing agent in the plating liquid L2 can be suppressed even in a standby time. That is, in the modification example, since the deterioration of the second plating liquid L2 used for the reduction plating processing can be suppressed, the inside of the via 120 can be better filled with the copper wiring.

In the modification example described so far, the second plating liquid L2 is produced by mixing the first plating liquid L1 and the third plating liquid L2a on the front surface of the substrate W. However, the present disclosure is not limited to this example. As another example, the second plating liquid L2 may be generated by mixing the first plating liquid L1 and the third plating liquid L2a above the substrate W (that is, before the discharged first plating liquid L1 and the third plating liquid L2a reach the substrate W).

In addition, in the above-described modification example, the second plating processing has been described for the example where the first plating liquid L1 and the third plating liquid L2a are both discharged. However, the present disclosure is not limited to this example. FIG. 10 is a diagram for describing a second plating processing according to another modification example of the exemplary embodiment.

As shown in FIG. 10, in the second plating processing, the controller 91 (see FIG. 1) controls the second plating liquid supply 54 to discharge only the third plating liquid L2a from the second plating liquid nozzle 541 onto the front surface of the substrate W on which the liquid film of the first plating liquid L1 is formed. Accordingly, the controller 91 allows the discharged third plating liquid L2a to be mixed with the liquid film of the first plating liquid L1 on the front surface of the substrate W, thus producing the second plating liquid L2.

Then, the controller 91 performs the reduction plating processing on the via 120 (see FIG. 4) by using the produced second plating liquid L2. As a result, the reduction plating film 134 (see FIG. 6) is formed in the via 120.

In the another modification example described so far, the reduction plating processing is performed after the surface layer of the seed layer 132 made of cobalt is replaced with the thin film 133 of copper by the displacement plating processing, the same as in the above-described exemplary embodiment. Therefore, according to this modification example, the inside of the via 120 can be successfully filled with the copper wiring, the same as in the above-described exemplary embodiment.

In addition, in the another modification example, since the deterioration of the second plating liquid L2 used for the reduction plating processing can be suppressed as in the above-described modification example, inside of the via 120 can be better filled with the copper wiring.

In the exemplary embodiment and various modification examples described so far, the via 120 is filled with the copper wiring (reduction plating film 134). However, the present disclosure is not limited to this example, and various types of recesses (for example, trenches, etc.) formed in the front surface the substrate W may be filled with the copper wiring.

A plating apparatus (the substrate processing apparatus 1) according to the exemplary embodiment includes the substrate holder 52 configured to hold the substrate W rotatably, the chemical liquid supply (the first plating liquid supply 53 and the second plating liquid supply 54) configured to supply the chemical liquid to the substrate W, and the controller 91 configured to control the individual components. Further, the controller 91 holds, with the substrate holder 52, the substrate W having the seed layer 132 of cobalt or the cobalt alloy formed in the recess (the via 120). The controller 91 performs, by using the first plating liquid L1 containing the copper ion, the displacement plating processing on the substrate W to replace the surface layer of the seed layer 132 with copper. Further, after the displacement plating processing, the controller 91 performs the reduction plating processing on the recess (the via 120) of the substrate W by using the second plating liquid L2 containing the copper ion and the reducing agent. Accordingly, the inside of the via 120 can be successfully filled with the copper wiring.

In addition, in the plating apparatus (the substrate processing apparatus 1) according to the exemplary embodiment, the chemical liquid supply is configured to supply, onto the substrate W, the first plating liquid L1 containing the reducing agent in the proportion smaller than a preset value and the third plating liquid L2a containing the reducing agent in the proportion larger than that of the first plating liquid L1. Further, the controller 91 performs the reduction plating processing by using the second plating liquid L2 which is produced by mixing the first plating liquid L1 and the third plating liquid L2a on the substrate W. Accordingly, the inside of the via 120 can be better filled with the copper wiring.

Further, in the plating apparatus (the substrate processing apparatus 1) according to the exemplary embodiment, the controller 91 controls the rotation speed of the substrate W to 1000 rpm or less while performing the displacement plating processing. Thus, the displacement plating processing can be performed uniformly on the entire surface of the substrate W.

Moreover, in the plating apparatus (the substrate processing apparatus 1) according to the exemplary embodiment, the controller 91 controls the rotation speed of the substrate to 100 rpm or less while performing the reduction plating processing. Therefore, the consumption amount of the second plating liquid L2 can be reduced.

### <Details of Plating Processing>

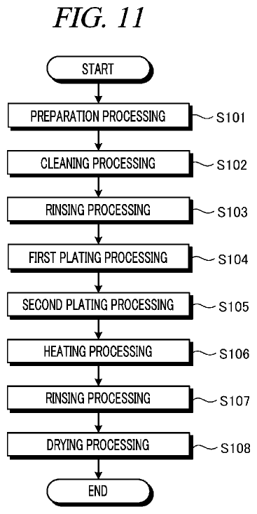

Now, referring to FIG. 11, details of the plating processing performed by the substrate processing apparatus 1 according to the exemplary embodiment will be discussed. FIG. 11 is a flowchart illustrating a processing sequence of the plating processing according to the exemplary embodiment.

First, the controller 91 controls the substrate transfer devices 13 and 17 to carry the substrate W into the plating unit 5 from the carrier C, and controls the substrate holder 52 to hold the substrate W, thus allowing the substrate W to be ready to be processed (process S101).

Then, the controller 91 performs a cleaning processing on the substrate W (process S102). In this case, the rotation motor 523 is first driven to rotate the substrate W at a preset rotation speed. Then, the nozzle arm 57 located at the retreat position (the position indicated by the solid line in FIG. 2) is moved to the discharge position above the center of the substrate W.

Subsequently, the cleaning liquid L3 is supplied to the substrate W being rotated from the cleaning liquid nozzle 551, so that the front surface of the substrate W is cleaned. As a result, the deposit or the like adhering to the substrate W is removed from the substrate W. The cleaning liquid L3 supplied to the substrate W is drained through the drain duct 583.

Thereafter, the controller 91 performs a rinsing processing on the substrate W (process S103). In this case, the rinse liquid L4 is supplied to the substrate W being rotated from the rinse liquid nozzle 561, so that the front surface of the substrate W is rinsed. As a result, the cleaning liquid L3 remaining on the substrate W is washed away. The rinse liquid L4 supplied to the substrate W is drained through the drain duct 583.

Afterwards, the controller 91 performs the first plating processing on the substrate W (process S104). In this case, the first plating liquid L1 is supplied from the first plating liquid nozzle 531 to the substrate W being rotated at 1000 rpm or less, so that the seed layer 132 of cobalt formed inside the via 120 is subjected to the displacement plating processing.

As a result, the thin film 133 of copper is formed on the surface layer of the seed layer 132 of cobalt. The first plating liquid L1 supplied to the substrate W is drained through the drain duct 583.

Next, the controller 91 performs the second plating processing on the substrate W (process S105). In this case, the second plating liquid L2 is supplied from the second plating liquid nozzle 541 to the substrate W being rotated at 100 rpm or less, so that the puddle of the second plating liquid L2 is formed on the front surface of the substrate W. As a result, the reduction plating film 134 is formed inside the via 120 by using the thin film 133 of copper formed in the first plating processing as the catalyst.

Then, the controller 91 performs a heating processing of heating the puddle of the second plating liquid L2 formed on the front surface of the substrate W by covering the substrate W with the cover body 6 and operating the heater 63 (process S106). This processing accelerates the formation of the reduction plating film 134. Further, since details of the processing of this process S106 has been described above, detailed description thereof will be omitted here.

Subsequently, the controller 91 performs a rinsing processing on the substrate W (process S107). In this case, the cover body 6 is retreated from above the substrate W. Then, the rotation motor 523 is driven to rotate the substrate W at the preset rotation speed.

Thereafter, the rinse liquid L4 is supplied to the substrate W being rotated from the rinse liquid nozzle 561, so that the front surface of the substrate W is rinsed. As a result, the second plating liquid L2 remaining on the substrate W is washed away. The rinse liquid L4 supplied to the substrate W is drained through the drain duct 583.

Next, the rinsed substrate W is subjected to a drying processing (process S108). In this case, the rotation speed of the substrate W is increased higher than the rotation speed in the rinsing processing (process S107) to rotate the substrate W at a high speed. As a result, the rinse liquid L4 remaining on the substrate W is scattered off, so that the substrate W is dried.

Upon the completion of this drying processing, the substrate W is taken out of the plating unit 5 by the substrate transfer device 17 to be transferred into to the delivery unit 14. Then, the substrate W transferred to the delivery unit 14 is taken out from the delivery unit 14 by the substrate transfer device 13 to be accommodated in the carrier C. Thus, the series of processes of the plating processing on the single sheet of substrate W are completed.

A plating method according to the exemplary embodiment includes a preparation processing (process S101), a first plating processing (process S104), and a second plating process (process S105). In the preparation processing (process S101), the substrate W having the seed layer 132 of cobalt or the cobalt alloy formed in the recess (via 120) is prepared. In the first plating processing (process S104), the displacement plating processing of replacing the surface layer of the seed layer 132 with the copper is performed on the substrate W by using the first plating liquid L1 containing the copper ions. In the second plating processing (process S105), the reduction plating processing is performed on the recess (via 120) of the substrate W by using the second plating liquid L2 containing the copper ions and the reducing agent after the first plating processing (process S104). As a result, the inside of the via 120 can be filled with the copper wiring successfully.

Further, in the plating method according to the exemplary embodiment, the second plating processing is performed by using the second plating liquid L2 which is produced by mixing the first plating liquid L1 containing the reducing agent in the proportion smaller than the preset value and the third plating liquid L2a containing the reducing agent in the proportion larger than that of the first plating liquid L1. Thus, the inside of the via 120 can be better filled with the copper wiring more successfully.

Moreover, in the plating method according to the exemplary embodiment, the first plating liquid may contain no reducing agent. Thus, the inside of the via 120 can be better filled with the copper wiring more successfully.

In addition, in the plating method according to the exemplary embodiment, the second plating processing (process S105) is performed on the substrate W wet with the first plating liquid L1. Thus, the inside of the via 120 can be better filled with the reduction plating film 134.

Further, in the plating method according to the exemplary embodiment, the seed layer 132 is formed by the CVD method. Thus, the inside of the via 120 can be better filled with the copper wiring.

Moreover, in the plating method according to the exemplary embodiment, the seed layer 132 has the thickness equal to or larger than 1 nm. Thus, the inside of the via 120 can be better filled with the copper wiring.

In addition, in the plating method according to the exemplary embodiment, the second plating liquid L2 has the temperature higher than that of the first plating liquid +1. Therefore, the overall processing time for the substrate W can be reduced.

So far, the exemplary embodiment of the present disclosure has been described. However, the present disclosure is not limited to the above-described exemplary embodiment, and various changes and modifications may be made without departing from the spirit of the present disclosure.

It should be noted that the above-described exemplary embodiment is illustrative in all aspects and is not anyway limiting. The above-described exemplary embodiment may be omitted, replaced and modified in various ways without departing from the scope and the spirit of claims.

### EXPLANATION OF CODES

1: Substrate processing apparatus (example of plating apparatus)
5: Plating unit
52: Substrate holder
53: First plating liquid supply (example of chemical liquid supply)
54: Second plating liquid supply (example of chemical liquid supply)
91: Controller
120: Via (example of recess)
132: Seed layer
133: Thin film
134: Reduction plating film
L1: First plating liquid
L2: Second plating liquid
L2a: Third plating liquid
W: Substrate

1. A plating method, comprising:
preparing a substrate having a seed layer of cobalt or a cobalt alloy formed in a recess;
performing a displacement plating processing on the substrate to replace a surface layer of the seed layer with copper by using a first plating liquid containing a copper ion;
performing, after the performing of the displacement plating processing, a reduction plating processing on the recess of the substrate by using a second plating liquid containing the copper ion and a reducing agent.

2. The plating method of claim 1,
wherein the performing of the reduction plating processing is performed by using the second plating liquid which is produced by mixing the first plating liquid containing the reducing agent in a proportion smaller than a preset value and a third plating liquid containing the reducing agent in a proportion larger than that of the first plating liquid.

3. The plating method of claim 1,
wherein the first plating liquid contains no reducing agent.

4. The plating method of claim 1,
wherein the performing of the reduction plating processing is performed on the substrate wet with the first plating liquid.

5. The plating method of claim 1,
wherein the seed layer is formed by a CVD method.

6. The plating method of claim 1,
wherein the seed layer has a thickness equal to or larger than 1 nm.

7. The plating method of claim 1,
wherein the second plating liquid has a temperature higher than that of the first plating liquid.

8. A plating apparatus, comprising:
a substrate holder configured to hold a substrate rotatably;
a chemical liquid supply configured to supply a chemical liquid to the substrate; and
a controller configured to control the substrate holder and the chemical liquid supply,
wherein the controller holds, with the substrate holder, the substrate having a seed layer of cobalt or a cobalt alloy formed in a recess,
the controller performs, by using a first plating liquid containing a copper ion, a displacement plating processing on the substrate to replace a surface layer of the seed layer with copper, and
the controller performs, after the displacement plating processing, a reduction plating processing on the recess of the substrate by using a second plating liquid containing the copper ion and a reducing agent.

9. The plating apparatus of claim 8,
wherein the chemical liquid supply is configured to supply, onto the substrate, the first plating liquid containing the reducing agent in a proportion smaller than a preset value and a third plating liquid containing the reducing agent in a proportion larger than that of the first plating liquid, and
the controller performs the reduction plating processing by using the second plating liquid which is produced by mixing the first plating liquid and the third plating liquid on the substrate.

10. The plating apparatus of claim 8,
wherein the controller controls a rotation speed of the substrate to 1000 rpm or less while performing the displacement plating processing.

11. The plating apparatus of claim 8,
wherein the controller controls a rotation speed of the substrate to 100 rpm or less while performing the reduction plating processing.
